(19) United States
(12) Patent Application Publication
(10) Pub. No.: US 2008/0142251 A1
(43) Pub. Date: Jun. 19, 2008

(54) CHIP COMPONENT

(75) Inventors: Tatsuya TSUJIGUCHI, Ishikawa-gun (JP); Yukihiro KITAICHI, Ishikawa-gun (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(73) Assignee: MURATA MANUFACTURING CO., LTD., Nagaokakyo-shi (JP)

(21) Appl. No.: 12/037,156

(22) Filed: Feb. 26, 2008

Related U.S. Application Data
(63) Continuation of application No. PCT/JP2007/063992, filed on Jul. 13, 2007.

(30) Foreign Application Priority Data
Aug. 2, 2006 (JP) 2006-211004

(51) Int. Cl. H05K 1/03

(52) U.S. Cl. 174/255

(57) ABSTRACT

A chip component is obtained by laminating a dielectric substrate, a first insulating layer provided on a principal surface of the dielectric substrate, and a second insulating layer covering substantially the entire first insulating layer. A circuit pattern includes a resonance line provided in an interface between the dielectric substrate and the first insulating layer. A plurality of through holes (H) are aligned n the first insulating layer along an extending direction of the circuit pattern at locations facing an area within the boundary of the circuit pattern.

### BACKGROUND OF THE INVENTION

1. Field of the Invention

The present invention relates to chip components having a circuit pattern on a dielectric substrate.

2. Description of the Related Art

A photolithographic is known for producing chip components. In the method, extremely accurate circuit patterns are formed by printing, exposing, and developing a photosensitive conductive paste on a dielectric substrate (See Japanese Unexamined Patent Application Publication No. 2001-210541).

Such a chip component provided with a circuit pattern formed using the photolithographic method has a low adhesion strength for the circuit pattern over the dielectric substrate. This may result in the circuit pattern becoming detached from the substrate due to thermal factors or mechanical factors. Once such detachment occurs in the circuit pattern, the conductivity of the circuit pattern is degraded, which degrades the reliability of the chip component.

To avoid such circuit pattern detachment and to improve the resistance to humidity, temperature, mechanical damage, and other environmental factors, a technique has been used in which an insulating layer (a glass layer) is formed by coating an insulating paste so as to cover the dielectric substrate and the circuit pattern, and baking the insulating paste. This technique prevents the circuit pattern from being detached by coating the circuit pattern with the insulating layer which has adhesion strength to the dielectric substrate that is greater than the adhesion strength of the circuit pattern to the dielectric substrate.

Typically, an insulator defining an insulating layer has a different linear expansion coefficient from a conductor defining a circuit pattern. The linear expansion coefficient of the insulator is also different from that of a dielectric defining a dielectric substrate. When a chip component is coated with the insulating layer, a stress remains in the insulating layer due to thermal stress generated during the heat treatment. When gas bubbles generated when baking a resin agent included in an insulating paste remain in the insulating layer, an increased amount of stress remains in the vicinity of the bubbles.

When the residual stress acts on the circuit pattern, the circuit pattern is deformed or becomes partially detached. This degrades the electrical characteristics of the chip component. Especially when the component is used at higher frequencies, the frequency characteristics thereof are greatly changed, which makes it difficult to obtain desired frequency characteristics. Variations in deformation of the circuit patterns and the locations at which such partial detachment occurs in the circuit patterns among the products (the chip components) create product-to-product variations in the electrical characteristics and the frequency characteristics. This decreases the yield rate.

### SUMMARY OF THE INVENTION

To overcome the problems described above, preferred embodiments of the present invention provide chip components in which the number of occurrences of deformation and partial detachment is decreased as compared to the known components.

According to a preferred embodiment of the present invention, a chip component includes a dielectric substrate and a first insulating layer covering a principal surface of the dielectric substrate. A circuit pattern is provided in an interface between the dielectric substrate and the first insulating layer. The first insulating layer includes a through hole having no conductor therein.

Since a hole including no conductor is provided in the first insulating layer, the gas generated during the baking of the first insulating layer is evacuated through the hole, which decreases the number and the size of gas bubbles in the vicinity of the hole after the baking. Since the deformation of the first insulating layer due to the baking of the first insulating layer and the following heat treatment is absorbed at the hole, the residual stress in the first insulating layer is decreased. Therefore, the stress imparted on the circuit pattern from the first insulating layer is also reduced. This decreases the deformation of the circuit pattern as compared to the known chip components, which prevents the circuit pattern from being partially detached.

Preferably, a second insulating layer is provided to cover substantially the entire first insulating layer.

With this configuration, the circuit pattern exposed from the through hole of the first insulating layer and the first insulating layer are covered by the second insulating layer. Thus, the environmental resistances of the circuit pattern and the first insulating layer are increased.

Preferably, the through hole of this preferred embodiment is provided at a location facing an area within the boundary of the circuit pattern.

With this configuration, the stress and the gas bubbles that remain in the vicinity of the circuit pattern in the first insulating layer are effectively decreased by providing the through hole at a location facing the circuit pattern. In addition, the detachment of the circuit pattern occurring from the external boundary area to the internal boundary thereof can be prevented by pressing an edge portion of the circuit pattern with the outer edge of the through hole.

A chip component according to another preferred embodiment of the present invention is obtained by aligning a plurality of the through holes along an extending direction of the circuit pattern.

With this configuration, the deformation of the first insulating layer is decreased along the circuit pattern.

A non-electrode containing portion within the boundary of the circuit pattern is preferably provided. The dielectric substrate and the first insulating layer contact each other via the non-electrode containing portion.

In general, the adhesion strength of the insulator defining the first insulating layer over the conductor defining the circuit pattern is less than the adhesion strength of the insulator defining the first insulating layer over the dielectric defining the dielectric substrate. Therefore, outstanding adhesion strength is distributed inside the circuit pattern by providing the non-electrode containing portion inside the circuit pattern. This effectively prevents the circuit pattern from being detached.

Preferably, side electrodes are provided in side surfaces of at least the dielectric substrate and the first insulating layer.

When the side electrodes are provided, the baking of the first insulating layer is applied to the dielectric substrate and then the side electrode is baked. The heat stress is applied to the first insulating layer when the side electrode is baked. However, the deformation and the detachment of the circuit pattern are prevented by the configuration according to preferred embodiments of the present invention even when the side electrode is provided.

A chip component according to another preferred embodiment of the present invention defines a resonance line of a stripline resonator provided by using the circuit pattern.

In typical stripline resonators, variations in resonance characteristics due to the deformation or the detachment of the circuit pattern are substantial. This configuration prevents variations in resonance characteristics of the chip component including the stripline resonator.

Preferred embodiments of the present invention provide a chip component in which the number of occurrences of the deformation and the detachment of the circuit pattern is greatly decreased. In addition, preferred embodiments of the present invention prevent a decrease in the yield rate and the product-to-product variations in the electrical characteristics, the frequency characteristics, and other characteristics.

Other features, elements, characteristics and advantages of the present invention will become more apparent from the following detailed description of preferred embodiments of the present invention with reference to the attached drawings.

### BRIEF DESCRIPTION OF DRAWINGS

FIGS. 1A and 1B are perspective views showing a chip component according to a preferred embodiment of the present invention.

FIG. 2 is an exploded perspective view of the chip component shown in FIG. 1.

FIGS. 3A to 3C are views showing three surfaces of the chip component shown in FIG. 1.

FIGS. 4A to 4E are views illustrating a process of producing the chip component shown in FIG. 1.

FIGS. 5A and 5B are views illustrating a chip component according to another preferred embodiment of the present invention.

### DETAILED DESCRIPTION OF THE PREFERRED EMBODIMENTS

A chip component according to preferred embodiments of the present invention is described with reference to drawings. The Cartesian coordinate system (X-Y-Z axes) shown in the drawings is used for the description.

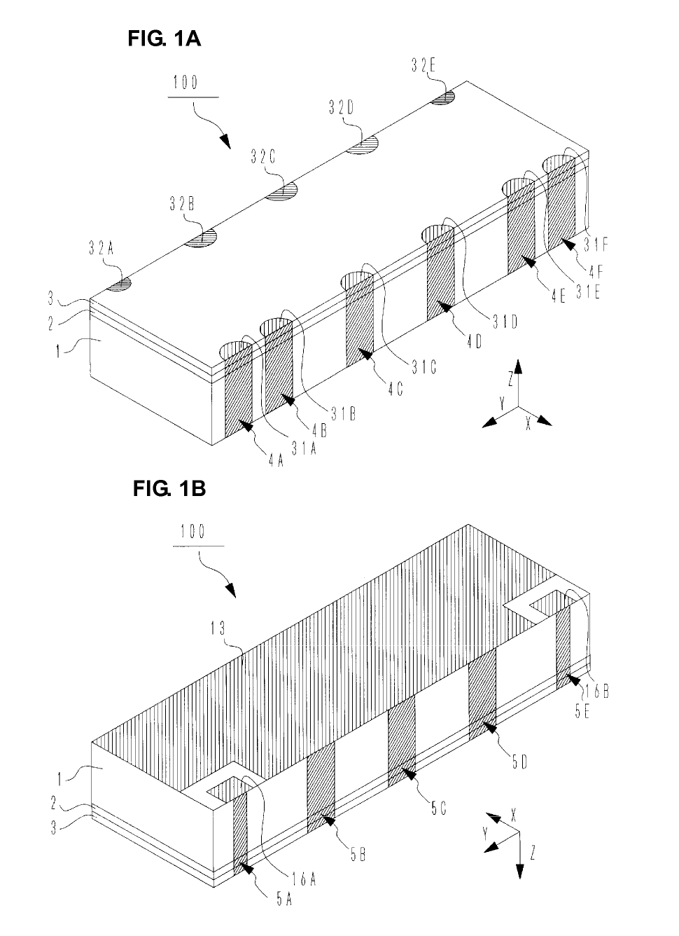

FIGS. 1A and 1B are external views of a chip component 100. FIG. 1A is a perspective view obtained by arranging the chip component 100 so that the front end thereof surfaces the front in the left of the drawing, and FIG. 1B is a perspective view obtained by rotating the chip component 100 around the Y-axis by 180 degrees from the position thereof in FIG. 1A.

The chip component 100 used in the description of the present preferred embodiment preferably is a substantially rectangular parallelepiped chip filter component in which an upper principal surface of a substantially rectangular flat plate dielectric substrate 1 is coated with a first glass layer 2 and an upper principal surface of the first glass layer is coated with a second glass layer 3. A filter is provided by a circuit pattern (not shown) of a stripline resonator between the dielectric substrate 1 and the first glass layer 2. The structure of the circuit pattern is described later.

In the chip component 100, preferably the substrate thickness (the Z-axis dimension) of the dielectric substrate 1 is about 500 μm, the thickness (the Z-axis dimension) of the first glass layer 2 is about 15 μm to about 30 μm, and the thickness (the Z-axis dimension) of the second glass layer 3 is about 15 μm to about 30 μm, for example. The outer dimensions of the chip component 100 preferably are approximately 9.5 mm in the X-axis dimension, approximately 2.2 mm in the Y-axis dimension, and approximately 0.56 mm in the Z-axis dimension, for example. These dimensions provide a small chip component having GHz band filter characteristics.

The dielectric substrate 1 is a substrate, preferably having a relative permittivity of 110 and preferably includes a ceramic dielectric, such as titanium oxide.

The first glass layer 2 includes insulators, such as crystalline SiO₂ and borosilicate glass. This first glass layer 2 is formed using a photolithographic method. The composition of the first glass layer 2 is adjusted so that the linear expansion coefficient thereof is substantially equal to that of the dielectric constituting the dielectric substrate 1. This decreases the thermal stress between the dielectric substrate 1 and the first glass layer 2.

The second glass layer 3 is formed by including an inorganic pigment, such as Al₂O₃, in the insulator, such as crystalline SiO₂ and borosilicate glass. The inorganic pigment included in the second glass layer 3 blocks light. Due to this light-blocking effect, the product name or other information (not shown) can be printed on the surface thereof.

Alternatively, embossment printing on the second glass layer 3 may be used. In addition, the second glass layer 3 and the first glass layer 2 may include inorganic pigments whose colors can sufficiently absorb ultraviolet rays. An increase in the absorption efficiency of the ultraviolet rays facilitates fine patterning using the photolithographic method. Note that a desired linear expansion coefficient may not be achieved with some types of inorganic pigments however. The composition and the dimensions of each of the dielectric substrate 1, the first glass layer 2, and the second glass layer 2 may be appropriately set based on required filter characteristics, environmental resistance, and adhesion strength between the dielectric substrate and the glass layer.

A plurality of protruding electrodes 31A to 31F and 32A to 32E are provided on an upper principal surface of the second glass layer 3. The protruding electrodes 31A to 31F and 32A to 32E are electrodes that protrude into the principal surface when side electrodes (described below) are printed. These electrodes may not be generated under some printing conditions. The electrodes also protrude to the bottom of the principal surface of the chip component 100 when the side electrodes are printed. The electrodes protruding to the bottom of the principal surface are integral with a lower surface electrode 13 and terminal electrodes 16A and 16B.

The glass layer 2 and the glass layer 3 are laminated on top of the principal surface of the substrate 1. This prevents the protruding electrodes 31A to 31F and 32A to 32E from causing a short circuit in an area in which wiring connection is not required in the principal surface pattern. The glass layers 2 and 3 increase the environmental resistance of the component 100 to thermal factors generated when the component is in use or external mechanical factors.

The lower principal surface of the dielectric substrate 1 is provided with the lower surface electrode 13 and the terminal electrodes 16A and 16B. The lower surface electrode 13 is connected to the ground potential when the chip component 100 is mounted in a mounting substrate. The terminal electrodes 16A and 16B are connected to high-frequency signal input/output terminals when the chip component 100 is mounted in the mounting substrate. The lower surface electrode 13 is arranged so as to cover substantially the entire lower principal surface of the dielectric substrate 1. The terminal electrodes 16A and 16B are provided in the vicinity of the two corresponding corners contacting the left side surface so as to be separated from the lower surface electrode 13. The lower surface electrode 13 and the terminal electrodes 16A and 16B preferably are electrodes of approximately 15 μm thickness (in the Z-axis direction) formed by printing a conductive paste using the screen printing or the like, and baking it, for example.

The right side surface and the left side surface of the chip component 100 are provided with the side electrodes 4A to 4F and the side electrodes 5A and 5E, respectively. The side electrodes 4A to 4F and 5A to 5E establish connections between a circuit pattern (not shown) on an interface between the dielectric substrate 1 and the first glass layer 2, and the lower surface electrode 13 or the terminal electrodes 16A and 16B. These electrodes preferably are approximately 15 μm in thickness (in the X-axis direction) and are substantially rectangular extending in the Z-axis direction from the lower principal surface of the dielectric substrate 1 to the upper principal surface of the second glass layer 3, for example. These are formed by printing, such as the screen printing, and baking. The side electrodes 4A to 4F provide connections between the protruding electrodes 31A to 31F and the lower surface electrode 13. The side electrodes 5B to 5D provide connections between the protruding electrodes 32B to 32D and the lower surface electrode 13. The side electrodes 5A and 5E provide connections between the side electrodes 32A and 32E, and the terminal electrodes 16A and 16B. Alternatively, instead of providing the side electrodes 4A to 4F and 5A to 5E, through holes penetrating through the dielectric substrate 1 may be provided so that the connection between the circuit pattern and the lower surface electrode 13 or the connections between the circuit pattern and the terminal electrodes 16A and 16B are provided.

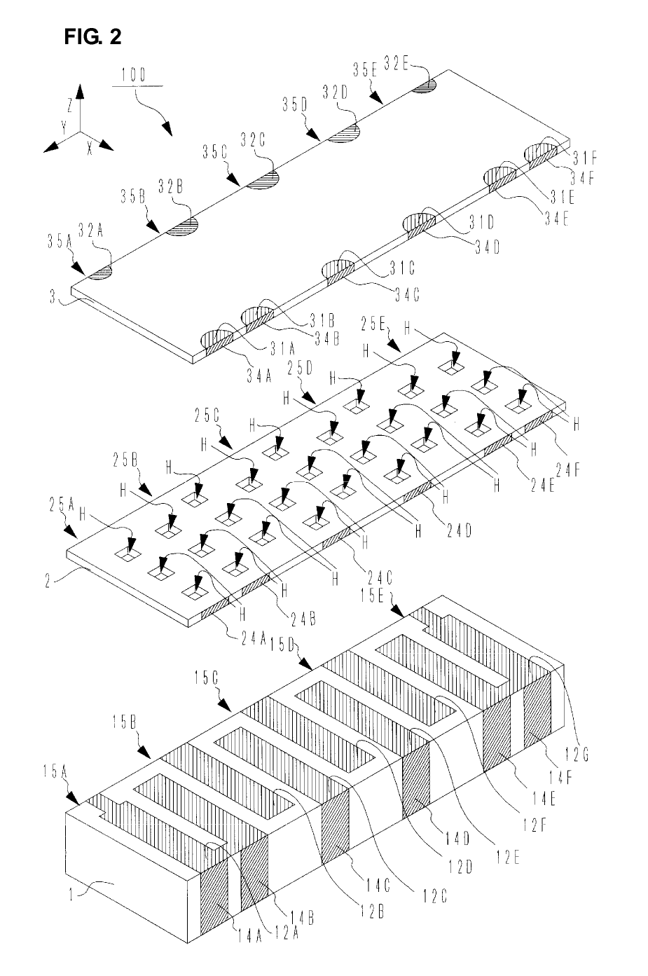

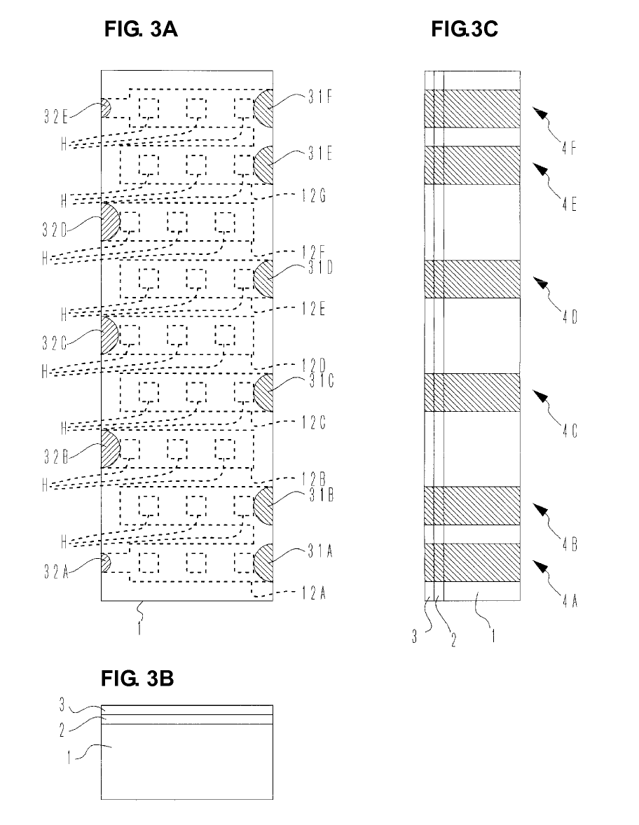

FIG. 2 illustrates an exploded perspective view of the chip component 100. FIGS. 3A to 2C are views illustrating three surfaces of the chip component 100. FIG. 3A is a view showing the upper principal surface thereof, FIG. 3B is a front view thereof, and FIG. 3C is a right-side view thereof.

The structure of the dielectric substrate 1 will now be described.

Side electrode patterns 14A to 14F defining the side electrodes 4A to 4F are provided in the right side surface of the dielectric substrate 1. A plurality of side electrode patterns 15A to 15E defining the side electrodes 5A to 5E is provided in the left side surface. Circuit patterns 12A to 12G are provided in the upper principal surface of the dielectric substrate 1. The circuit patterns 12A to 12G preferably are silver electrodes, each of which has an electrode thickness (the Z-axis dimension) of approximately 6 μm, and each of which is formed by the photolithographic method using a photosensitive silver paste, for example. Each of the circuit patterns 12A to 12G defines a quarter-wavelength resonator.

The circuit pattern 12A is a silver electrode. To be more specific, a shape is obtained by arranging two substantially rectangular electrodes in parallel and connecting them in the right side of the upper principal surface of the dielectric substrate 1. The two substantially rectangular electrodes are arranged such that the side electrode patterns 14A and 14B extend to the upper principal surface, and the width of each remains unchanged. Each of the two substantially rectangular electrodes defines a microstrip line resonator along with the lower surface electrode 13. These substantially rectangular electrodes are connected to the lower surface electrode 13 via the side electrode patterns 14A and 14B to be comb-line coupled with each other. Of the two stripline resonators in the circuit pattern 12A, the stripline resonator in the front side enables an open end thereof to be connected to the terminal electrode 16A via the side electrode pattern 15A.

The circuit pattern 12G is also a silver electrode that has substantially the same shape as the circuit pattern 12A. To be more specific, a shape is obtained by arranging two substantially rectangular electrodes in parallel and connecting them in the right side of the upper principal surface of the dielectric substrate 1. The two substantially rectangular electrodes are arranged such that the side electrode patterns 14E and 14F extend to the upper principal surface, and the width of each remains unchanged. Each of these two substantially rectangular electrodes defines a microstrip line resonator along with the lower surface electrode 13. These substantially rectangular electrodes are connected to the lower surface electrode 13 via the side electrode patterns 14E and 14F to be comb-line coupled with each other. Of the two stripline resonators in the circuit pattern 12G, the stripline resonator in the rear side enables an open end thereof to be connected to the terminal electrode 16B via the side electrode pattern 15E.

The circuit patterns 12B to 12F preferably are substantially rectangular silver electrodes and each define a microstrip line resonator along with the lower surface electrode 13. The circuit patterns 12C and 12E are connected to the lower surface electrode 13 via the side electrode patterns 14C and 14D, respectively. The circuit patterns 12B, 12D, and 12F are connected to the lower surface electrode 13 via the side electrode patterns 15B, 15C, and 15D, respectively.

The electrode dimensions (the line widths) and the intervals (the line intervals) of the circuit patterns 12A to 12G in the Y-axis direction are adjusted to achieve required frequency characteristics. This means that the line widths and the line intervals are not necessarily equal. In this case, the line widths of the striplines are approximately 1000 μm except for the ones at the ends.

The two microstrip line resonators in the circuit pattern 12A are comb-line coupled. Interdigital coupling is achieved between the microstrip line resonator in the rear side of the circuit pattern 12A and the microstrip line resonator of the circuit pattern 12B. Interdigital coupling is achieved between the microstrip line resonator of the circuit pattern 12B and the microstrip line resonator of the circuit pattern 12C. Interdigital coupling is achieved between the microstrip line resonator of the circuit pattern 12C and the microstrip line resonator of the circuit pattern 12D. Interdigital coupling is achieved between the microstrip line resonator of the circuit pattern 12D and the microstrip line resonator of the circuit pattern 12E. Interdigital coupling is achieved between the microstrip line resonator of the circuit pattern 12E and the microstrip line resonator of the circuit pattern 12F. Interdigital coupling is achieved between the microstrip line resonator of the circuit pattern 12F and the microstrip line resonator in the front side of the circuit pattern 12G. The two microstrip line resonators of the circuit pattern 12G are comb-line coupled with each other.

Therefore, the present chip component defines a bandpass filter provided with a nine-staged resonator. The shapes of the circuit patterns 12A to 12G comply with product specifications. Each of the patterns may have any suitable shape in accordance with the product specifications. Other than the filters, the chip component can be applied to circuit patterns having a variety of shapes. In particular, it is preferable that the component is applied to a component that utilizes the resonance generated by the circuit pattern, such as a filter, a balun, an oscillator, or an LC resonator.

The structure of the first glass layer 2 will now be described.

The right side surface of the first glass layer 2 is provided with side electrode patterns 24A to 24F defining the side electrodes 4A to 4F. The left side surface is provided with side electrode patterns 25A to 25E defining the side electrodes 5A to 5E.

The first glass layer 2 is provided with a plurality of through holes H whose locations correspond to the circuit patterns 12A to 12G provided in the dielectric substrate 1. This first glass layer 2 is formed by a photolithographic method using a photosensitive glass paste. Use of the photosensitive glass paste enables the through holes H to be formed by exposure. Here, three of the through holes H are arranged in the longitudinal direction of each circuit pattern (stripline). In the longitudinal and lateral dimensions observed from the principal surface, each of the through holes H preferably has a rounded-off square outline with sides of approximately 800 μm, which is less than 1000 μm, the dimension in the lateral direction of the corresponding circuit pattern, for example. Each of the through holes is preferably arranged approximately 100 μm apart from the corresponding edges of adjacent ones in the lateral direction of the corresponding circuit pattern, for example. The edges of each through hole in the lateral direction of the corresponding circuit pattern are covered with the outer glass.

The first glass layer 2 provided with through holes H is laminated on the dielectric substrate 1 so as to be tightly adhered thereto. This decreases the sizes and the number of gas bubbles (not shown) adjacent to the through holes H in the chip component 100 according to the present preferred embodiment. The stress in the vicinity of the circuit patterns is decreased. The tight adhesions between the dielectric substrate 1 and the circuit patterns 12A to 12G are therefore maintained. The environmental resistances of the circuit patterns 12A to 12G to humidity, temperature, mechanical damage, and other environmental factors are outstanding. The advantages of the structure according to preferred embodiments of the present invention are equally obtained regardless of the thickness of the first glass layer 2. The through holes H are not necessarily configured to be square. The through holes H may be configured to be rectangular, circular, or polygonal instead of square.

If the through holes H are not provided, the density of the adhesion between the first glass layer 2 and the dielectric substrate 1 is reduced particularly when the dimension of the circuit pattern in the lateral direction thereof preferably is at least approximately 400 μm, for example. This makes it difficult to produce a chip component 100 having practical filter characteristics. However, by using the through holes according to preferred embodiments of the present invention, a chip component 100 can be produced which has practical filter characteristics.

The structure of the second glass layer 3 will now be described.

The second glass layer 3 is a glass layer having a light blocking function formed by screen-printing a glass paste and baking it. The right side of the second glass layer 3 is provided with side electrode patterns 34A to 34F defining the side electrodes 4A to 4F. The left side of the second glass layer 3 is provided with a plurality of side electrode patterns 35A to 35E defining the side electrodes 5A to 5E. The protruding electrodes 31A to 31F and 32A to 32E are provided on the upper principal surface. By providing the second glass layer 3 with a light blocking function, printing can be performed on the surface. In addition, the circuit pattern cannot be seen from the surface, which provides confidentiality regarding the specific arrangement of the circuit pattern.

With the dielectric substrate 1, the first glass layer 2, and the second glass layer 3, the chip component 100 according to the present preferred embodiment is constructed. Since the first glass layer 2 and the second insulating layer are configured so as to cover the circuit patterns 12A to 12G, the chip component with high environmental resistance to humidity, temperature, mechanical damage, and other environmental factors is constructed. Providing a plurality of through holes H decreases the occurrence of deformation and detachment of the circuit patterns of the chip component 100.

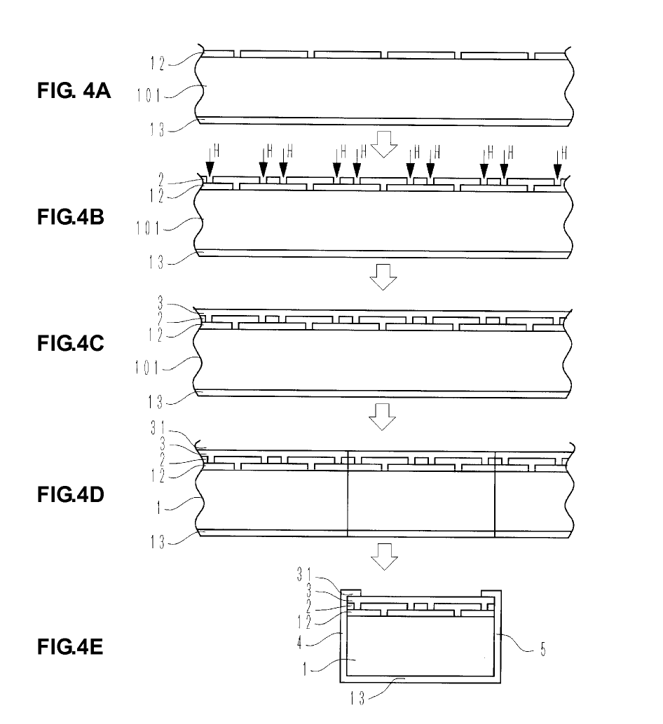

A process of producing the chip component 100 will now be described. FIGS. 4A to 4E are views illustrating the chip component 100 at each stage of the production process.

In the process of producing the chip component 100, the following steps are performed.

Printing, exposing, and developing using the photolithographic method are performed on the upper principal surface of a dielectric motherboard 101 to form a photosensitive silver paste pattern, which is formed into the silver electrode circuit patterns 12 via baking. The screen printing is applied on the lower principal surface thereof to form a conductive paste pattern, which is formed into the lower surface electrode 13 and terminal electrodes (not shown) via baking.

Printing, exposing, and developing using the photolithographic method are performed on the upper principal surface of the dielectric motherboard 101 to form a photosensitive glass paste pattern, which is formed into the first glass layer 2 via baking. Ultraviolet irradiation is performed on the first glass layer 2 except for the areas in which the through holes H are to be formed during the exposure. The glass pastes at the locations corresponding to the through holes H are washed and removed during the development. The gas obtained via baking is evacuated from the through holes H, which prevents the gas bubbles from being generated in the vicinity of each of the through holes H, that is, the circuit patterns 12A to 12G. The expansion of the photosensitive glass paste is absorbed by the through holes H. Therefore, the stress produced during the curing thereafter is significantly decreased.

The glass paste is laminated on the upper principal surface of the first glass layer 2 using screen printing to form the second glass layer 3 via the baking. Although the first glass layer 2 expands due to the heat stress during the baking, the through holes H absorb the expansion of the first glass layer 2. The stress caused by this heat stress is therefore significantly decreased.

A plurality of chip components 100 is obtained from the dielectric motherboard 101 constructed in the above manner.

The silver paste patterns are formed on the sides of the chip component 100 using screen printing to form the side electrodes 4 and 5 via the baking. Although the first glass layer 2 expands due to the heat stress during the baking, the through holes H absorb the expansion of the first glass layer 2. The stress caused by this heat stress is therefore significantly decreased.

By producing the chip component 100 according to the present preferred embodiment via the above-described steps, a decrease in the yield rate and a decrease in product-to-product (chip components) variations in the electrical characteristics, the frequency characteristics and other characteristics are prevented.

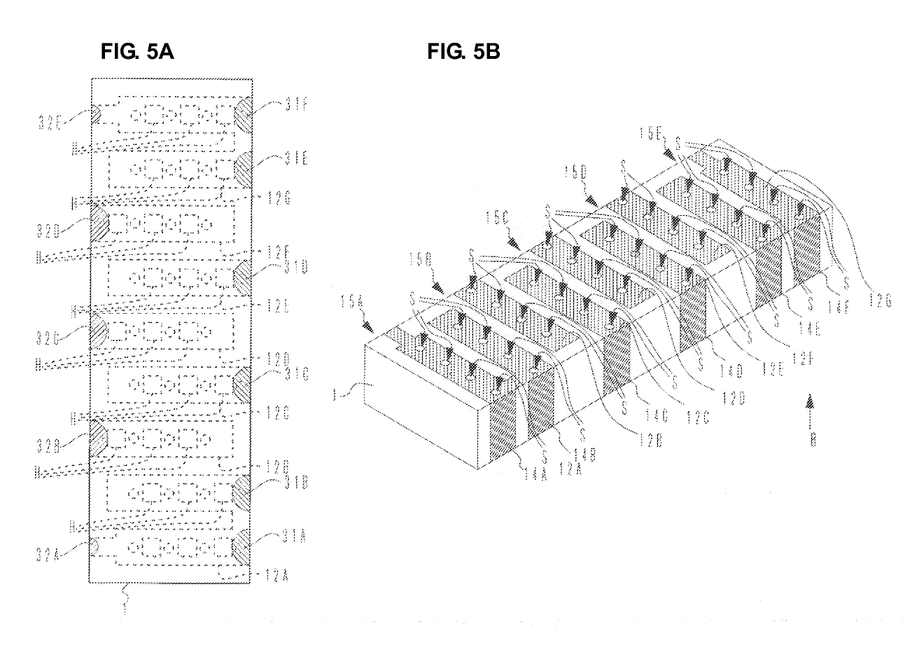

A second preferred embodiment will now be described with reference to FIGS. 5A to 5B. FIG. 5A is a top transparent view of a chip component 200 according to the present preferred embodiment, and FIG. 5B is a perspective view of the dielectric substrate 1.

The structure of the chip component 200 according to the present preferred embodiment differs from that of the component 100 in that a plurality of non-electrode containing portions S is provided within the boundaries of the circuit patterns 12A to 12G.

In each of the circuit patterns 12A to 12G provided in the dielectric substrate 1, four non-electrode containing portions are arranged so as not to face the through holes H.

Each of the plurality of non-electrode containing portions S preferably is substantially circular and is provided in the center of the corresponding electrodes. The portions are provided in the center of the electrodes in order to avoid the outer edges of the circuit patterns in which the current is concentrated. This prevents variations in the electrical characteristics of the circuit patterns caused by providing the non-electrode containing portions S. In addition, the dielectric substrate 1 and the first glass layer 2 are arranged in contact with each other via the non-electrode containing portions S. This enables high adhesion strength to be provided within the circuit patterns. The non-electrode containing portions S may be configured to be rectangular, semiregular, elliptic or any other suitable shape, instead of circular.

Therefore, the chip component according to the present preferred embodiment achieves a further decrease in the occurrences of deformation and partial detachment as compared to the first preferred embodiment.

The above description is for illustrative purposes in every aspect and thus considered limiting. The scope of the present invention is indicated by the scope of the claims, not the above-described preferred embodiments. The scope of the present invention is also intended to include meaning equivalents to the scope of the claims and every modification within the scope.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A chip component comprising:
a dielectric substrate; and
a first insulating layer provided on a principal surface of the dielectric substrate; wherein
a circuit pattern is provided at an interface between the dielectric substrate and the first insulating layer; and
the first insulating layer includes a through hole having no conductor therein.

2. The chip component according to claim 1, further comprising a second insulating layer covering substantially the entire first insulating layer.

3. The chip component according to claim 1, wherein the through hole is provided in a location facing an area within the boundary of the circuit pattern.

4. The chip component according to claim 1, wherein a plurality of the through holes are aligned along an extending direction of the circuit pattern.

5. The chip component according to claim 1, further comprising a non-electrode containing portion disposed within the boundary of the circuit pattern, wherein the dielectric substrate and the first insulating layer are in contact with each other via the non-electrode containing portion.

6. The chip component according to claim 1, wherein side electrodes are provided in side surfaces of at least the dielectric substrate and the first insulating layer.

7. The chip component according to claim 1, wherein the circuit pattern defines a resonance line of a stripline resonator.
